(19) United States
(12) Patent Application Publication
(10) Pub. No.: US 2006/0269851 A1
(43) Pub. Date: Nov. 30, 2006

(54) Photomask and method for conveying information associated with a photomask substrate

(76) Inventors: Larry E. Frisa, Round Rock, TX (US); Franklin D. Kalk, Austin, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/462,876

(22) Filed: Aug. 7, 2006

Related U.S. Application Data
(63) Continuation of application No. PCT/US05/05097, filed on Feb. 17, 2005.
(60) Provisional application No. 60/545,243, filed on Feb. 17, 2004.

(51) Int. Cl. G03F 1/00

(52) U.S. Cl. 430/5; 430/945

(57) ABSTRACT

A method for conveying information about a photomask substrate is disclosed. The method includes heating an area of a photomask substrate located between a top surface and a bottom surface of the photomask substrate with a laser. The heat applied to the area of the substrate forms a mark inside the substrate that stores information identifying the photomask substrate.

### CROSS REFERENCE TO RELATED APPLICATION

This application is a continuation of International Patent Application No. PCT/US2005/005097 filed Feb. 17, 2005, which claims priority from U.S. Provisional Patent Application Ser. No. 60/545,243, filed Feb. 17, 2004 by Larry E. Frisa, et al., and entitled “Photomask and Method for Increasing Surface Flatness of a Photomask Substrate.”

### TECHNICAL FIELD OF THE INVENTION

The present invention relates in general to photolithography and, more particularly to a photomask and method for conveying information associated with a photomask substrate.

### BACKGROUND OF THE INVENTION

As semiconductor device manufacturers continue to produce smaller devices, the requirements for photomasks used in the fabrication of these devices continue to tighten. Photomasks, also known as reticles or masks, typically consist of substrates (e.g., high-purity quartz or glass) that have an absorber layer (e.g., chromium or chromium oxynitride) formed on the substrate. The absorber layer includes a pattern representing a circuit image that may be transferred onto semiconductor wafers in a lithography system. As feature sizes of semiconductor devices decrease, the corresponding circuit images on the photomask also become smaller and more complex. Consequently, the quality of the mask has become one of the most crucial elements in establishing a robust and reliable semiconductor fabrication process.

In order to maintain the quality of a photomask, it may be important to trace a photomask throughout a manufacturing process. Conventional tracking techniques use identification marks placed on the surface of a photomask substrate. These marks may be placed on the surface by using a physical or laser scribing technique. A scribing process, however, may generate unwanted particles that contaminate the surface of the substrate and cause defect induced pattern errors in a patterned layer formed on the substrate. The defects and particles may degrade the quality of the substrate, which also may affect the quality of an image projected onto a surface of a semiconductor wafer.

In another conventional tracking technique, a bar code including information related to a photomask may be formed in the absorber layer during a lithography process used to create the circuit pattern. Although the bar code provides information about the photomask, the bar code may be formed on the photomask only during the lithography process used to form the circuit pattern in the absorber layer and the information in the bar code cannot be updated during another step in the manufacturing process. Additionally, the absorber layer may be removed when the substrate is recycled and, therefore, any information in the bar code associated with the substrate will be lost.

### SUMMARY OF THE INVENTION

In accordance with teachings of the present invention, disadvantages and problems associated with placing identification information on a photomask substrate have been substantially reduced or eliminated. In a particular embodiment, a photomask substrate includes a mark formed inside the photomask substrate that stores identification information associated with the photomask substrate.

In accordance with one embodiment of the present invention, a method for conveying information associated with a photomask substrate includes heating an area of a photomask substrate located between a top surface and a bottom surface of the photomask substrate with a laser. The heat applied to the area of the photomask substrate is used to form a mark inside the photomask substrate that stores information identifying the photomask substrate.

In accordance with another embodiment of the present invention, a photomask includes a substrate having a border region that substantially surrounds a mask field. A mark located between a top surface and a bottom surface of the substrate is formed by heating an area of the substrate with a laser. The mark operates to store information identifying the substrate.

In accordance with a further embodiment of the present invention, a photomask includes a substrate having a border region substantially surrounding a mask field. A mark located between a top surface and a bottom surface of the substrate is formed by heating an area of the substrate with a laser. The mark operates to alter stress in the substrate such that at least one of the top surface and bottom surfaces have an increased flatness.

Important technical advantages of certain embodiments of the present invention include a mark formed inside a substrate that improves the quality of a photomask. During a manufacturing process, one or more lasers may be used to heat a localized area inside of a photomask substrate such that a disruption is created in the substrate. The mark may be created under the surface of the substrate by moving the laser to other localized areas. Since the mark is located inside of the substrate, the surface remains free of unwanted particles and defects that can affect the quality of the image projected onto a semiconductor wafer.

Another important technical advantage of certain embodiments of the present invention includes a mark that stores information for identifying a photomask in a manufacturing process. During the lifetime of a photomask, it may be beneficial to track certain information (e.g., processing information and/or photomask properties) associated with the photomask. A mark formed in the photomask substrate may be able to store the information such that the photomask may be identified at any step of a photomask and/or semiconductor manufacturing process. Since the mark is located inside the substrate, the mark may be used to identify information associated with the substrate even if the substrate is recycled.

Another important technical advantage of certain embodiments of the present invention includes a mark that reduces warping of a photomask substrate. Stress inherent in the photomask substrate and/or created by the absorber layer and/or pellicle assembly may cause the substrate to warp leading to registration errors in an image projected onto a semiconductor wafer. By forming the mark at one or more locations within the photomask substrate where stress is more dominant, stress of the substrate may be altered to create a flatter surface.

All, some, or none of these technical advantages may be present in various embodiments of the present invention. Other technical advantages will be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a cross-sectional view of a photomask assembly that includes a mark containing identification information in accordance with teachings of the present invention;

FIG. 2 illustrates a block diagram of a system for forming a mark in a photomask substrate in accordance with teachings of the present invention;

FIG. 3 illustrates a perspective view of a photomask substrate including a mark formed below a first surface in accordance with teachings of the present invention;

FIG. 4 illustrates a top view of a photomask substrate including a mark formed below a first surface in accordance with teachings of the present invention; and

FIG. 5 illustrates a top view of a photomask substrate including a mark that reduces stress in the substrate in accordance with teachings of the present invention.

### DETAILED DESCRIPTION OF THE INVENTION

Preferred embodiments of the present invention and their advantages are best understood by reference to FIGS. 1 through 5, where like numbers are used to indicate like and corresponding parts.

FIG. 1 illustrates a cross-sectional view of photomask assembly 10 including a mark containing identification information. Photomask assembly 10 includes photomask 12 coupled to pellicle assembly 14. Substrate 16 and patterned layer 18 form photomask 12, otherwise known as a mask or reticle, that may have a variety of sizes and shapes, including but not limited to round, rectangular, or square. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 12 may further be a binary mask, a phase shift mask (PSM), an optical proximity correction (OPC) mask or any other type of mask suitable for use in a lithography system. In other embodiments, photomask 12 may be a step and flash imprint lithography (SFIL) mask that does not include pellicle assembly 14.

Photomask 12 includes patterned layer 18 formed on substrate 16 that, when exposed to electromagnetic energy in a lithography system, projects a pattern onto a surface of a semiconductor wafer (not expressly shown). Substrate 16 may be a transparent material such as quartz, synthetic quartz, fused silica, magnesium fluoride (MgF₂), calcium fluoride (CaF₂), or any other suitable material that transmits at least seventy-five percent (75%) of incident light having a wavelength between approximately 10 nanometers (nm) and approximately 450 nm. In an alternative embodiment, substrate 16 may be a reflective material such as silicon or any other suitable material that reflects greater than approximately fifty percent (50%) of incident light having a wavelength between approximately 10 nm and 450 nm.

Patterned layer 18 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In an alternative embodiment, patterned layer 18 may be a partially transmissive material, such as molybdenum silicide (MoSi), which has a transmissivity of approximately one percent (1%) to approximately thirty percent (30%) in the UV, DUV, VUV and EUV ranges. In a further embodiment, photomask 12 may be a SFIL mask having a pattern etched into substrate 16 such that there is no absorber layer formed on substrate 16.

Frame 20 and pellicle film 22 may form pellicle assembly 14. Frame 20 is typically formed of anodized aluminum, although it could alternatively be formed of stainless steel, plastic or other suitable materials that do not degrade or outgas when exposed to electromagnetic energy within a lithography system. Pellicle film 22 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 22 may be prepared by a conventional technique such as spin casting.

Pellicle film 22 protects photomask 12 from contaminants, such as dust particles, by ensuring that the contaminants remain a defined distance away from photomask 12. This may be especially important in a lithography system. During a lithography process, photomask assembly 10 is exposed to electromagnetic energy produced by a radiant energy source within the lithography system. The electromagnetic energy may include light of various wavelengths, such as wavelengths approximately between the I-line and G-line of a Mercury arc lamp, or DWV, VUV or EUV light. In operation, pellicle film 22 is designed to allow a large percentage of the electromagnetic energy to pass through it. Contaminants collected on pellicle film 22 will likely be out of focus at the surface of the wafer being processed and, therefore, the exposed image on the wafer should be clear. Pellicle film 22 formed in accordance with the teachings of the present invention may be satisfactorily used with all types of electromagnetic energy and is not limited to lightwaves as described in this application.

Photomask 12 may be formed from a photomask blank using a standard lithography process. In a lithography process, a mask data file that includes data for patterned layer 18 may be generated from a mask layout file. The mask layout file may include polygons that represent transistors and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. The polygons for each layer may be converted into a mask data file that represents one layer of the integrated circuit. Each mask data file may be used to generate a photomask for the specific layer.

During a photomask or semiconductor manufacturing process, it may be beneficial to place identification information on photomask 12 to track photomask 12 throughout the manufacturing process. A conventional technique for placing identification information on a photomask involves forming a bar code including information related to the photomask in an absorber layer during a lithography process used to create a circuit pattern on the photomask. Although the bar code may provide information about the photomask, the information cannot be updated as the photomask moves through a manufacturing process. Additionally, the bar code will be removed when the substrate is re-used.

In contrast, mark 24 formed inside substrate 16 between top surface 17 and bottom surface 19 improves the quality of photomask 12 because mark 24 may be formed in substrate 16 without creating particles, and thus defects on top and bottom surfaces 17 and 19 of substrate 16. Mark 24 may be formed using one or more lasers having suitable wavelengths to heat an area of substrate 16. When the heat is applied to substrate 16, disruptions (e.g., cracks or bubbles) may be formed in substrate 16 without damaging top and bottom surfaces 17 and 19 of substrate 16. The bubbles may form mark 24 under a surface of substrate 16. By forming mark 24 inside substrate 16, defects created on the surface by traditional scribing techniques may be eliminated.

Mark 24 may be located in substrate 16 such that the placement of mark 24 alters stress in substrate 16 to prevent substrate 16 from warping. For example, mark 24 may be located at one or more outer edges of substrate 16 where the effects of stress may be more dominant. In other embodiments, mark 24 may be located at one or more corners of substrate 16. By altering the stress of substrate 16 in areas where stress may cause substrate 16 to warp, the flatness of at least one of top and bottom surfaces 17 and 19 of substrate 16 may be increased and registration errors caused by warping may be reduced or even eliminated.

In some embodiments, mark 24 may be a two-dimensional shape (e.g., squares, rectangles, circles, ovals, triangles, and lines), a three-dimensional shape (e.g., spheres, cubes, cylinders and blocks) or any other pattern designed to alter stress in substrate 16. In other embodiments, mark 24 may be a bar code, a two-dimensional digital code, such as a data matrix, a three-dimensional digital code, alphanumeric characters, two-dimensional shapes (e.g., squares, rectangles, circles, ovals, triangles, and lines), three-dimensional shapes (e.g., spheres, cubes, cylinders and blocks) and any other suitable pattern that stores data to convey information about substrate 16 and/or photomask 12 when scanned with a light source or manually read by the human eye.

In one embodiment, mark 24 may be coded in order to store information about manufacturing procedures performed on photomask 12. The photomask manufacturing procedures may include, but are not limited to, a lithography process, a develop process, an etch process, a clean process, an inspection process, a metrology process, a pellicle application, and any other procedures that may be performed on photomask 12 during a photomask manufacturing process. In another embodiment, mark 24 may be coded to include various information about the properties of photomask 12, including but not limited to, photomask type (e.g., binary, OPC, PSM, etc.), wavelength compatibility (e.g., 365 nm, 248 nm, 193 nm, 156 nm, etc.), substrate type (e.g., quartz, MgF₂, CaF₂, etc.), absorber layer material (e.g., chrome, MOCN, MoSi, etc.), pellicle type (e.g., nitrocellulose, cellulose acetate, amorphous fluoropolymer, etc.) and/or any other properties associated with photomask 12 that may be used to determine how photomask assembly 10 may be manufactured or used in a semiconductor manufacturing process. In other embodiments, mark 24 may be coded to store information indicating the number of times that substrate 16 was reused to create another photomask, the number of times that photomask 12 was cleaned, and/or the number of times that pellicle assembly 14 was removed from and/or remounted on photomask 12. In further embodiments, mark 24 may include any combination of the photomask manufacturing procedures, the photomask properties and the number of times that the photomask was cleaned, reused and/or the pellicle assembly was removed and/or remounted

Mark 24 may be formed in any portion of substrate 16 before, during and/or after any one of the photomask manufacturing procedures are performed on photomask 12 during a photomask manufacturing process. For example, mark 24 may be formed before an absorber layer is deposited on substrate 16 to form a photomask blank. In another embodiment, mark 24 may be formed after the photomask blank is created but before the absorber layer is patterned to form photomask 12. In a further embodiment, mark 24 may be formed after patterned layer 18 on photomask 12 is created. In other embodiments, mark 24 may be formed in substrate 16 after photomask 12 has been used in a semiconductor manufacturing process.

In some embodiments, mark 24 may be used to identify photomask assembly 10 in order to determine the specific procedures that should be used to manufacture photomask assembly 10 and/or the specific semiconductor manufacturing processes that photomask assembly 10 is compatible with. For example, mark 24 may include coded information representing a lithography process for forming a pattern in patterned layer 18, a cleaning process for removing any contaminants from the surfaces of photomask 12 and/or the properties of photomask 12 such that photomask 12 may be matched with a compatible pellicle assembly 14. Mark 24 may be read by scanning a light beam, such as a laser or a diffuse light source, over mark 24. The light beam may detect changes in the signal to noise ratio, indicating the presence of a disruption in the substrate. The changes may be detected by transmitting the beam of light through substrate 16 to a detector on the opposite side of the light source or by reflecting the beam of light off of mark 24 inside of substrate 16. In one embodiment, the light source may be located orthogonal to the surface of substrate 16. In another embodiment, the light source may be located at an angle to the surface such that mark 24 may be read correctly.

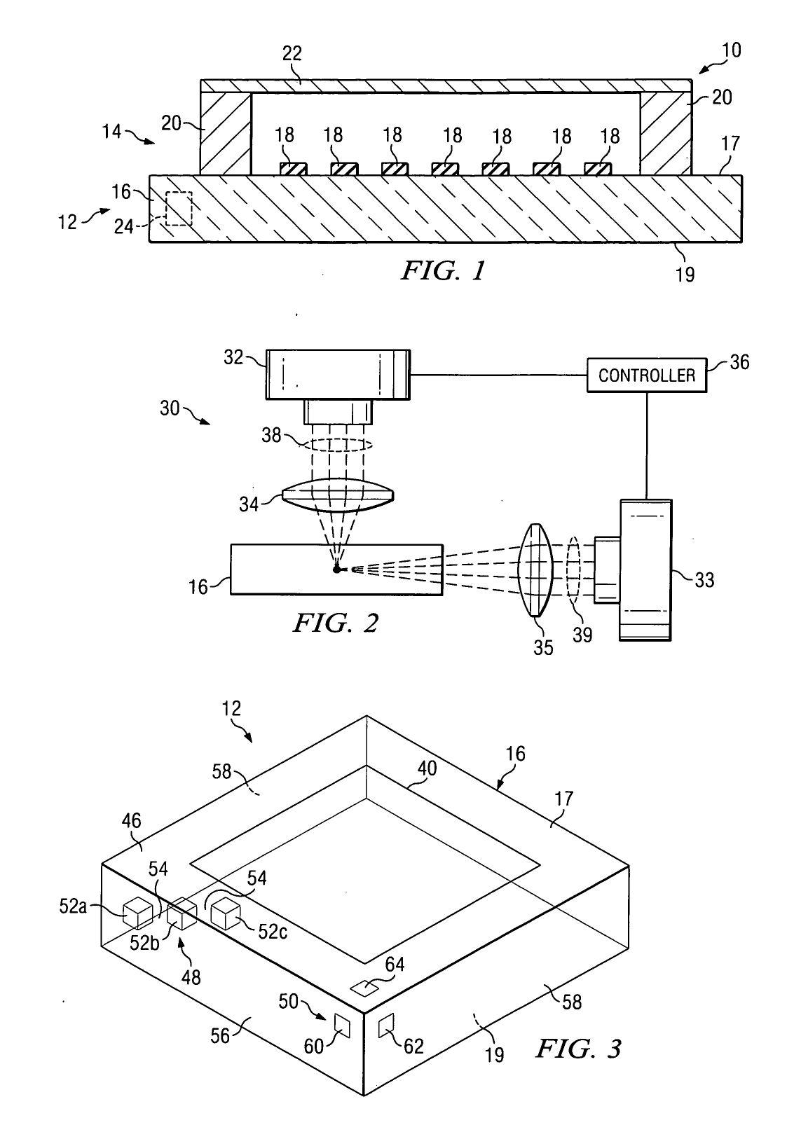

FIG. 2 illustrates a block diagram of system 30 used to form a mark in a photomask substrate. In the illustrated embodiment, system 30 includes lasers 32 and 33, focusing lenses 34 and 35 and controller 36. Lasers 32 and 33 may be any type of laser that produces a wavelength suitable for forming mark 24 in substrate 16. In some embodiments, the wavelength of laser depends on the material used to form substrate 16. Controller 36 may be coupled to lasers 32 and 33 and may instruct lasers 32 and 33 to respectively generate beams 38 and 39. Beams 38 and 39 may be respectively projected towards focusing lenses 34 and 35, which focus beams 38 and 39 to a single focal point within substrate 16. In one embodiment, controller 36 may move lasers 32 and 33 such that the focal point of beams 38 and 39 may be placed at different locations within substrate 16 to form mark 24. In another embodiment, substrate 16 may be placed on a moveable platform (not expressly shown) and controller 36 may also be coupled to the moveable platform. Controller 36 may instruct the moveable platform to move substrate 16 to a specific location such that the focal point of beams 38 and 39 is located at the appropriate point within substrate 16.

Beams 38 and 39 may interact with substrate 16 at the focal point. The intensity of the radiation at the focal point disturbs or locally destructs substrate 16 in the vicinity of the focal point. This may be achieved, for example, by heating, melting, and/or expanding substrate 16 at the focal point to cause cracking or bubbling. By placing the focal point at a location in substrate 16 far enough below any surface, the surfaces and surrounding areas of substrate 16 may be unaffected.

The local destruction or disruption may create an imperfection within substrate 16, which has a lower translucence than the surrounding areas. As a result, the point of local destruction appears as a foreign object, such as a bubble, encased within substrate 16. The characteristics of the local disruption, e.g., the size of the point, may be controlled by adjusting the intensity or length of the laser emission. A series of local disruptions (e.g., cracks or bubbles) can be coordinated to form two-dimensional and three-dimensional images, such as mark 24, within substrate 16.

Lasers 32 and 33 may be a YAG laser, a hard body impulse laser, a pulsed solid-state laser, a Q-spoiled laser or any other suitable laser that may create local disruptions in substrate 16. In one embodiment, lasers 32 and 33 may have an energy output of approximately fifty Mega Joules (50 MJ), a pulse frequency of approximately one Hertz (1 Hz) and a pulse length of approximately ten nanoseconds (10 ns). In other embodiments, the characteristics of lasers 32 and 33 may be selected so that the laser emission disrupts, melts or causes a microfracture of substrate 16 at the focal point without affecting the area surrounding the focal point.

Although the illustrated embodiment includes two lasers, a system to form marks inside a photomask substrate may also be formed with one or more than two lasers. Additionally, system 30 may be used to form a mark inside any suitable structure that can be altered without damaging the surfaces of the structure (e.g., a lens used in a scanner or stepper).

FIG. 3 illustrates a perspective view of photomask 12 including marks formed inside substrate 16. Photomask 12 may be formed by substrate 16 and mask field 40. Substrate 16 may include top surface 17 and bottom surface 19. Mask field 40 may be formed on top surface 17 and may include patterned layer 18 as illustrated in FIG. 1. Mask field 40 may be generally defined as the area to be imaged onto the surface of a wafer (not expressly shown). Border region 46 may surround mask field 40 and may expose top surface 17 of substrate 16. In another embodiment, a layer of absorbing material may be formed on border region 46.

In the illustrated embodiment, mark 48 is formed in one corner of substrate 16 and mark 50 is formed in another corner of substrate 16. In another embodiment, a mark may only be formed in one corner of substrate 16. In other embodiments, marks may be formed in multiple locations, including the edges and/or corners, of substrate 16. For example, marks 48 and 50 may be located at any position within substrate 16 that alters stress within substrate 16 to prevent warping. By altering the stress in substrate 16, marks 48 and 50 may improve the flatness characteristics of top surface 17 and bottom surface 19.

In some embodiments, marks 48 and 50 may contain information about photomask assembly, including substrate 16, patterned layer 18 and pellicle assembly 14. For example, marks 48 and 50 may contain information relating to the processes used to manufacture photomask assembly 10, the properties of photomask 12 and pellicle assembly 14, the manufacturing processes that photomask assembly is compatible with, and any other appropriate information related to photomask assembly 10 and the use of photomask assembly 10 in a manufacturing process.

In one embodiment, mark 48 may be a three-dimensional pattern (e.g., a three-dimensional linear bar code) including blocks 52 and spaces 54 that may be read in any one of three-dimensions (e.g., the same information may be obtain if the mark is scanned from top surface 17 and side surfaces 56 and 58 of substrate 16). Each of blocks 52 may have the same or different dimensions and provide the same or unique information. For example, each of blocks 52 may include information related to the properties of photomask 12, the processes used to manufacture photomask 12 and the use of photomask 12 in a specific semiconductor manufacturing process or this information may be included in individual blocks (e.g., block 52a may include the photomask properties, block 52b may include the photomask manufacturing processes and block 52c may include compatible semiconductor manufacturing processes). In one embodiment, spaces 54 may be the same such that blocks 52 are separated by the same distance. In another embodiment, spaces 54 may be different sizes such that blocks 52 are separated by different distances.

In one embodiment, mark 50 may be a two-dimensional pattern including shapes, such as rectangles and squares, that may be read in two-dimensions. For example, mark 50 may be formed from data matrices 60, 62 and 64 that include digital code and may store more than approximately 3,000 characters in a small space. In one embodiment, data matrices 60, 62 and 64 may contain the same information such that mark 50 may be scanned in more than one dimension to obtain the identification information. In another embodiment, data matrices 60, 62 and 64 may contain different information. For example, data matrix 60 may contain information about the substrate material and data matrix 62 may contain information about the manufacturing process or lithography process used to create photomask 12.

Marks 48 and 50 may be formed between top surface 17 and bottom surface 19 of substrate 16. In one embodiment, marks 48 and 50 may extend from slightly under top surface 17 to slightly above bottom surface 19 such that marks 48 and 50 are contained completely within substrate 16. For example, mark 48 may be located off-axis along a diagonal of substrate 16. In another embodiment, mark 50 may be located on-axis (e.g., oriented along the x, y, or z axis) at a specific distance below top surface 17 on side surfaces 56 and 58. For example, substrate 16 may have a depth of approximately one-quarter inch (¼ in) and mark 50 may be located approximately one-eighth inch (⅛ in) below top surface 17. By placing marks 48 and 50 substantially inside substrate 16, defects or contamination that interfere with a photomask and/or semiconductor manufacturing process may be eliminated from either or both of top surface 17 and bottom surface 19.

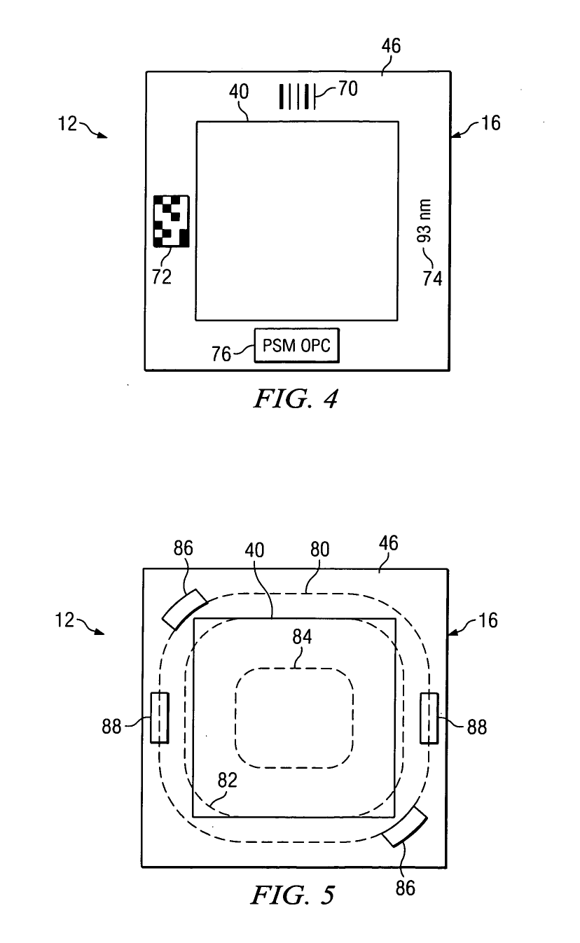

FIG. 4 illustrates a top view of photomask 12 including multiple patterns formed inside of substrate 16. Photomask 12 includes substrate 16 having mask field 40 and border region 46 formed thereon. Substrate 16 may further include marks 70, 72, 74 and 76 (generally referred to as marks 70). Mark 70 may be any one dimensional pattern, such as a bar code, that may be used to store a digital representation of alphanumeric characters. Mark 72 may be any two-dimensional pattern, such as a data matrix, that may be used to store a digital representation of alphanumeric characters. The information stored in marks 70 and 72 may be retrieved by scanning marks 70 and 72 with a light source (not expressly shown) connected to a computer (not expressly shown) that has the ability to interpret the scanned digital information.

Marks 74 and 76 may be any combination of alphanumeric characters that convey information about photomask 12. As illustrated, mark 74 may be used to indicate that photomask 12 may be used with a specific exposure wavelength in a lithography process. In another embodiment, mark 74 may indicate the minimum or maximum exposure wavelength for use with photomask 12 during a lithography process. Mark 76 may be used to convey information about the photomask type. For example, the letters “PSM” may indicate that the photomask is a phase shift mask and the letters “OPC” may indicate that the photomask includes optical proximity correction features in the mask field. Either of marks 74 and 76 may be read by an operator, technician or engineer in a photomask and/or semiconductor manufacturing facility.

Marks 70 may be located substantially inside substrate 16 at a specific depth. In one embodiment, marks 70 may be located at a depth half way between the top and bottom surfaces of substrate 16 (e.g., top surface 17 and bottom surface 19 as shown in FIG. 3). In another embodiment, marks 70 may be located slightly below the top surface or slightly above the bottom surface. Marks 70 may additionally be located a specific distance from the edges of substrate 16. In one embodiment, marks 70 may be located in border region 46 equidistant between the edges of substrate 16 and mask field 40. In another embodiment, marks 70 may be located closer to either the edges of substrate 16 or mask field 40. The positions of marks 70 may alter the stress in substrate 16 to prevent warping and to increase the flatness of either or both of top surface 17 and bottom surface 19.

FIG. 5 illustrates a top view of photomask 12 including marks formed inside of substrate 16 that reduce and/or alter stress in substrate 16. In the illustrated embodiment, the effects of stress may be more dominant along the outer edges of substrate 16, as shown by stress lines 80, 82 and 84 (generally referred to as stress lines 80). Mark 86 may be shaped to align with and be parallel to one or more of stress lines 80 in order to prevent substrate 16 from warping due to internal stress, the stress exerted by patterned layer 18 (as illustrated in FIG. 1) formed in mask field 40 and/or the stress exerted by pellicle assembly 14. Mark 86 may be located at one or more corner regions. As illustrated, mark 86 may be located at diagonal corner regions. In another embodiment, mark 86 may be located at two adjacent corners regions. In other embodiments, mark 86 may be located in all four corner regions.

Substrate 16 may alternatively or additionally include mark 88 to prevent warping. In one embodiment, mark 88 may be shaped to align with and be parallel to stress lines 80. In another embodiment, mark 88 may be a rectangle positioned to be aligned with and parallel to the edges of substrate 16. Mark 88 may be located on one or more edges of substrate 16. As illustrated, mark 88 may be located on opposing edges. In another embodiment, mark 88 may be located on two adjacent edges. In other embodiments, mark 86 may be located on all four edges. By placing marks 86 and 88 near one or more outer edges and/or at one or more of the corner regions of substrate 16, either one of or both of top surface 17 and bottom surface 19 may be flatter, which is desirable for increasing the quality of a photomask.

In some embodiments, marks 86 and 88 may store information associated with photomask assembly 10 in addition to altering the stress in photomask 12. For example, marks 86 and 88 may include information relating to the procedures used to manufacture photomask assembly 10, the properties of photomask assembly 10, the number of times photomask 12 has been cleaned and/or recycled, the number of times pellicle assembly 14 has been removed and/or remounted and/or any other information that may be used by a photomask and/or semiconductor manufacturer to identify photomask assembly 10.

Although the present invention has been described with respect to a specific preferred embodiment thereof, various changes and modifications may be suggested to one skilled in the art and it is intended that the present invention encompass such changes and modifications fall within the scope of the appended claims.

1. A method for conveying information about a photomask substrate, comprising:
heating an area of a photomask substrate with a laser, the area located between a top surface and a bottom surface of the substrate; and
forming a mark inside the photomask substrate based on the heat applied to the area of the photomask substrate, the mark operable to store information identifying the photomask substrate.

2. The method of claim 1, further comprising the mark including a plurality of bubbles.

3. The method of claim 2, further comprising the bubbles located off-axis such that the mark may be scanned in at least two dimensions.

4. The method of claim 1, wherein heating the area of the substrate comprises creating a localized disruption.

5. The method of claim 1, further comprising the mark including at least one of a bar code, a data matrix, a three-dimensional block and an alphanumeric character.

6. The method of claim 1, further comprising the stored information including at least one manufacturing process.

7. The method of claim 1, further comprising the stored information including at least one photomask property.

8. The method of claim 1, wherein the stored information comprises at least one of substrate reuse information, substrate cleaning information and pellicle removal information.

9. The method of claim 1, further comprising the mark operable to alter stress in the substrate such that at least one of the top surface and the bottom surface have an increased flatness.

10. The method of claim 1, further comprising forming the mark inside the substrate after any step performed in a photomask manufacturing process.

11. A photomask, comprising:
a substrate including a border region substantially surrounding a mask field; and
a mark formed between a top surface and a bottom surface of the substrate by heating an area of the substrate with a laser, the mark operable to store information identifying the substrate.

12. The photomask of claim 11, further comprising a patterned layer formed on at least a portion of the top surface of the substrate in the mask field.

13. The photomask of claim 12, further comprising a pellicle assembly mounted on the substrate in the border region.

14. The photomask of claim 11, further comprising the mark including at least one of a bar code, a data matrix, a three-dimensional block and an alphanumeric character.

15. The photomask of claim 11, further comprising the stored information including at least one manufacturing process.

16. The photomask of claim 11, further comprising the stored information including at least one photomask property.

17. The photomask of claim 11, wherein the stored information comprises at least one of substrate reuse information, substrate cleaning information and pellicle removal information.

18. The photomask of claim 11, further comprising the mark operable to alter stress in the substrate such that at least one of the top surface and the bottom surface have an increased flatness.

19. A photomask, comprising:
a substrate including a border region substantially surrounding a mask field; and
a mark formed between a top surface and a bottom surface of the substrate by heating an area of the substrate with a laser, the mark operable alter stress in the substrate such that at least one of the top surface and the bottom surface have an increased flatness.

20. The photomask of claim 19, further comprising:
a patterned layer formed on at least a portion of the top surface of the substrate in the mask field; and
a pellicle assembly mounted on the substrate in the border region.

21. The photomask of claim 19, further comprising the mark including a plurality of bubbles.

22. The photomask of claim 19, further comprising the mark operable to store information identifying at least one photomask manufacturing process.

23. The photomask of claim 19, further comprising the mark operable to store information identifying at least one photomask property.

24. The photomask of claim 19, further comprising the mark operable to store at least one of substrate reuse information, substrate cleaning information and pellicle removal information.

25. The photomask of claim 19, further comprising the mark including at least one of a bar code, a data matrix, a three-dimensional block and an alphanumeric character.

26. The photomask of claim 19, further comprising the mark located on at least one of a corner of the substrate and an edge of the substrate.
